(19) United States
(12) Patent Application Publication
(10) Pub. No.: US 2025/0040029 A1
(43) Pub. Date: Jan. 30, 2025

(54) FLEXIBLE WIRING BOARD, ELECTRONIC MODULE, ELECTRONIC UNIT, AND ELECTRONIC APPARATUS

(71) Applicant: CANON KABUSHIKI KAISHA, Tokyo (JP)

(72) Inventors: HIROKI SAITO, Kanagawa (JP); YU OGAWA, Tokyo (JP); TOSHIYUKI YOSHIDA, Kanagawa (JP); KEISUKE ABE, Kanagawa (JP)

(21) Appl. No.: 18/781,689

(22) Filed: Jul. 23, 2024

(30) Foreign Application Priority Data
Jul. 26, 2023 (JP) 2023-121791
Apr. 23, 2024 (JP) 2024-070113

(51) Int. Cl. H05K 1/02; H05K 1/11; H05K 1/18

(52) U.S. Cl. CPC H05K 1/0225; H05K 1/0281; H05K 1/118; H05K 1/181; H05K 2201/0715; H05K 2201/10151

(57) ABSTRACT

A flexible wiring board includes a plurality of signal lines, a shielding layer disposed to overlap with the plurality of signal lines in a planar view, and an insulating member disposed on a side opposite to a side where the shielding layer for the plurality of signal lines is disposed. The shielding layer is provided with openings. The shielding layer includes a first region having an opening ratio higher than a predetermined value and a second region having an opening ratio lower than the opening ratio of the first region. The second region is disposed at a position where the second region overlaps with the insulating member and the plurality of signal lines in a planar view. A boundary between the first region and the second region is disposed via a space to the insulating member in a planar view.

### BACKGROUND

### Field

The present disclosure relates to a flexible wiring board, an electronic module, an electronic unit, and an electronic apparatus.

### Description of the Related Art

Electronic apparatuses including mobile phones, smart phones, and digital cameras have a wiring board for performing signal processing. With the increasing demands for higher performance and smaller sizes, there have been used foldable flexible wiring boards (flexible circuits) having a signal wiring circuit formed on a flexible insulating film.

Japanese Patent Application Laid-Open No. 2000-077802 discusses a wiring board provided with a shield having a predetermined opening pattern.

Japanese Patent Application Laid-Open No. 2018-200779 discloses a flexible cable provided with a shield having a mesh structure.

However, the characteristics demanded for wiring boards are increasing day by day and yet some of more sophisticated functions have not been satisfied.

With wiring boards included in electronic apparatuses, the number of wiring lines has been increased because of high-density mounting. In addition, with the increase in the amount of communicated information, the transmission rate of signals sent in wiring lines also increases, thereby increasing radiated noise generated from wiring boards. Japanese Patent Application Laid-Open No. 2000-077802 discusses a wiring board provided with a shield having a predetermined opening pattern to reduce radiated noise while ensuring high-frequency signal transmission characteristics.

However, if a shielding layer is applied to a wiring board as discussed in Japanese Patent Application Laid-Open No. 2000-077802, it becomes hard to satisfy both the flexibility and the high-frequency signal transmission characteristics.

Therefore, a need exists for wiring boards that satisfy both the flexibility and the high-frequency signal transmission characteristics.

### SUMMARY

The present disclosure provides wiring board configurations that overcome the deficiencies and satisfy both the flexibility and the high-frequency signal transmission characteristics described above.

According to some embodiments, a flexible wiring board includes a plurality of signal lines, a shielding layer disposed to overlap with the plurality of signal lines in a planar view, and an insulating member disposed on a side opposite to a side where the shielding layer for the plurality of signal lines is disposed. The shielding layer is provided with openings. The shielding layer includes a first region having an opening ratio higher than a predetermined value and a second region having an opening ratio lower than the opening ratio of the first region. The second region is disposed at a position where the second region overlaps with the insulating member and the plurality of signal lines in a planar view. A boundary between the first region and the second region is disposed via a space to the insulating member in a planar view.

Further features of the present disclosure will become apparent from the following description of exemplary embodiments with reference to the attached drawings.

### BRIEF DESCRIPTION OF THE DRAWINGS

FIG. 1 is a top view illustrating an electronic unit according to a first exemplary embodiment.

FIG. 2 is an enlarged view illustrating an essential part in FIG. 1.

FIG. 3A is a cross-sectional view taken along the A-A line in FIG. 2. FIG. 3B is a cross-sectional view taken along the B-B line in FIG. 2. FIG. 3C is a cross-sectional view taken along the C-C line in FIG. 2.

FIG. 4 is a schematic view illustrating a system used for evaluating the transmission characteristics of flexible wiring boards according to exemplary embodiments and comparative examples.

FIG. 5 is a schematic view illustrating a system used for evaluating the flexibility of the flexible wiring boards according to the exemplary embodiments and the comparative examples.

FIG. 6 is a top view illustrating a wiring board according to a second exemplary embodiment.

FIG. 7 is a top view illustrating a wiring board according to a third exemplary embodiment.

FIG. 8 is a top view illustrating a wiring board according to a fourth exemplary embodiment.

FIG. 9 is a top view illustrating a wiring board according to a fifth exemplary embodiment.

FIG. 10 is a top view illustrating a wiring board according to a sixth exemplary embodiment.

FIG. 11 is a top view illustrating a wiring board according to an eighth exemplary embodiment.

FIG. 12 is a top view illustrating a wiring board according to a first comparative example.

FIG. 13 is a top view illustrating a wiring board according to a second comparative example.

FIG. 14 illustrates a digital camera (imaging apparatus) as an example of an electronic apparatus according to an exemplary embodiment.

FIG. 15 is a top view illustrating an electronic unit according to a third exemplary embodiment.

FIG. 16A is a cross-sectional view taken along the A-A line in FIG. 15. FIG. 16B is a cross-sectional view taken along the B-B line in FIG. 15. FIG. 16C is a cross-sectional view taken along the C-C line in FIG. 15.

FIGS. 17A to 17F are top views illustrating wiring boards according to a seventh to a twelfth exemplary embodiments, respectively.

FIGS. 18A to 18C are top views illustrating wiring boards according to a third to a fifth comparative examples, respectively.

### DESCRIPTION OF THE EMBODIMENTS

Various exemplary embodiments, features, and aspects of the present disclosure will be described below with reference to the accompanying drawings. The following exemplary embodiments are to be considered as examples of exemplary embodiments, and the present disclosure is not limited thereto.

As described above, with wiring boards included in electronic apparatuses, the number of wiring lines has been increased because of high-density mounting. In addition, with the increase in the amount of communicated information, the transmission rate of signals sent in wiring lines also increases, thereby increasing radiated noise generated from wiring boards. Japanese Patent Application Laid-Open No. 2000-077802 discusses a wiring board provided with a shield having a predetermined opening pattern to reduce radiated noise while ensuring high-frequency signal transmission characteristics.

However, if a shielding layer is applied to a wiring board as discussed in Japanese Patent Application Laid-Open No. 2000-077802, it becomes hard to satisfy both the flexibility and the high-frequency signal transmission characteristics. A first exemplary embodiment provides a flexible wiring board that satisfies both the flexibility and the high-frequency signal transmission characteristics.

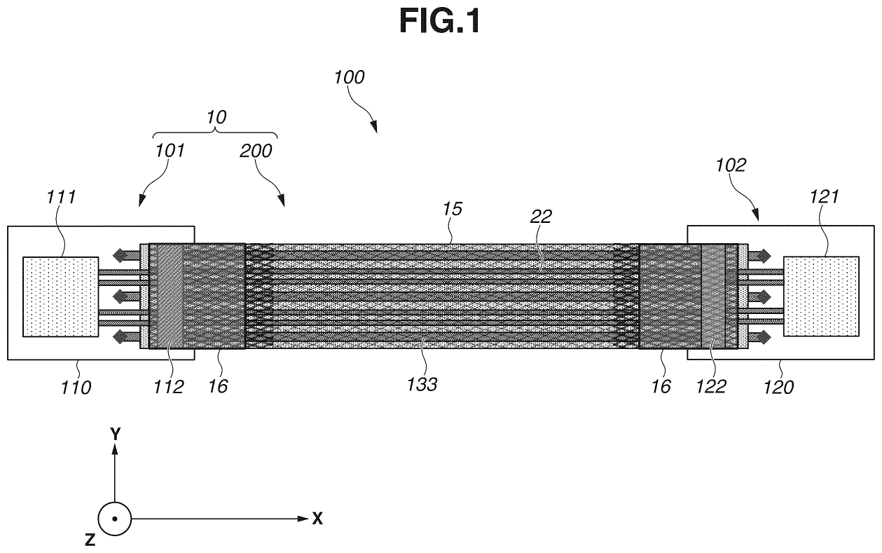

A wiring board 200 according to the first exemplary embodiment will be described below with reference to FIGS. 1, 2, and 3.

FIG. 1 is a top view illustrating an electronic unit 100 having the wiring board 200. The electronic unit 100 includes a circuit board 101, a circuit board 102, and the wiring board 200 for electrically connecting the circuit boards 101 and 102. The circuit boards 101 and 102 are, for example, printed circuit boards. The wiring board 200 is a flexible wiring board, for example, a flexible printed wiring board. A product in which the wiring board 200 and at least either one of the circuit boards 101 and 102 are connected with each other can be referred to as an electronic module 10. For example, the electronic unit 100 can be configured by connecting the electronic module 10 in which the wiring board 200 is connected to the circuit board 101 and connecting the wiring board 200 of the electronic module 10 to the circuit board 102. An electronic apparatus including the electronic unit 100 can also be configured.

As illustrated in FIG. 1, the wiring board 200 extends in the X direction as the longitudinal direction. The wiring board 200 includes a plurality of signal lines 22 and a plurality of ground lines 133, and each of the signal lines 22 and each of the ground lines 133 extend in the X direction. The plurality of the signal lines 22 and the plurality of the ground lines 133 are arranged at certain intervals in the Y direction as the lateral direction intersecting with the X direction. The Z d/irection orthogonal to the X and Y directions is the direction of the thickness of the wiring board 200. The wiring board 200 having flexibility is bendable and deformable.

According to the present exemplary embodiment, the plurality of the signal lines 22 and the plurality of the ground lines 133 are arranged in parallel in the Y direction when viewed from the Z direction (in a planar view). However, at least a part of these signal lines 22 and ground lines 133 may be arranged in parallel in the Y direction in a planar view.

The wiring board 110 configuring the circuit board 101 is mounted with a connector 112. The connector 112 is electrically connected to the semiconductor apparatus 111 by the conductor pattern on the wiring board 110. Like the wiring board 110, the wiring board 120 configuring the circuit board 102 is mounted with a connector 122. The connector 122 is electrically connected to the semiconductor apparatus 121 by the conductor pattern on the wiring board 120.

Around the connector 112 of the wiring board 200, an insulating member 16 is disposed. If the thickness with the insulating member 16 increases, it is possible to suppress the solder of the connector 112 and the wiring pattern from being peeled off when attaching or detaching the connector.

The wiring boards 110 and 120 can be, for example, rigid wiring boards including a resin substrate or ceramic substrate that are printed wiring boards (rigid printed boards).

The above-described configuration allows the semiconductor apparatuses 111 and 121 to be electrically and communicably connected with each other via the wiring boards 110, 200, and 120. In this case, the wiring board 200 may be directly connected with the wiring boards 110 and 120 by soldering without interposing the connectors 112 and 122, respectively. The wiring boards 110 and 200 may be directly connected by soldering, and the wiring boards 120 and 200 may also be connected via a connector.

The wiring board 200 is provided with a shielding layer 15 for preventing electromagnetic interference (EMI) due to radiated noise caused by the electromagnetic radiation generated from the signal lines 22. The following description will be made centering on a case where the shielding layer 15 has a mesh pattern, but the shape of the shielding layer 15 is not limited thereto.

The insulating member 16 is provided near the edges of the wiring board 200 to prevent damage to the wiring board 200 when attaching and detaching the connectors 112 and 122. The insulating member 16 is formed of, for example, a reinforcing plate, a resin film made of polyimide, or an adhesive tape. The insulating member 16 is desirably formed of a material having higher Young's modulus than a base material 12. The base material 12 may also be partially thickened.

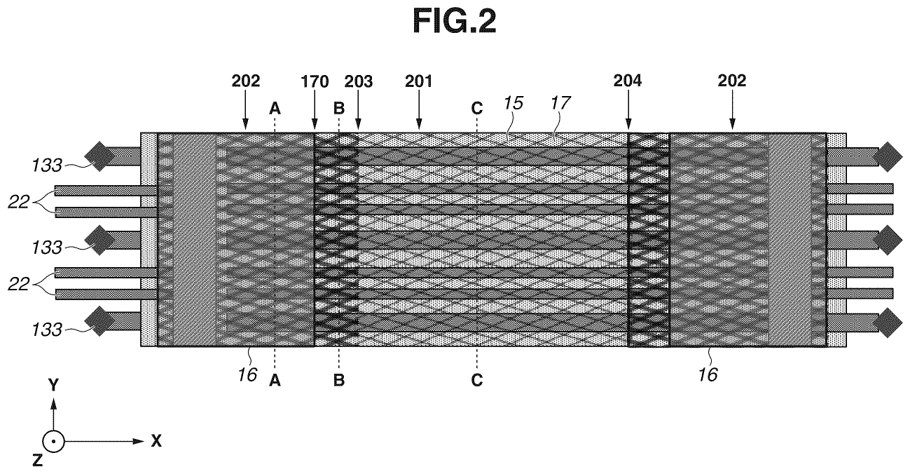

FIG. 2 is an enlarged view illustrating an essential part in FIG. 1. As illustrated in FIG. 2, the shielding layer 15 according to the present exemplary embodiment is provided with openings 17 and is divided into a region 202 (second region), a region 201 (first region) and, a region 202 (third region) in this order in the +X direction by the ratio of the area of the opening 17 per unit area (this ratio is referred to as an opening ratio). The unit area includes a part of the shielding layer 15 and a part of the plurality of the openings 17. The region 201 has an opening ratio higher than a predetermined opening ratio, and the region 202 has an opening ratio lower than the opening ratio of the region 201. The boundary between the region 202 (second region) and the region 201 is a boundary 203, and the boundary between the region 201 and the region 202 (third region) is a boundary 204. In other words, the boundaries 203 and 204 are edge surfaces of the second region. According to the present exemplary embodiment, the regions 202 and 201 have different line widths, and the positions where the line width changes in the +X direction are equivalent to the boundaries 203 and 204. Even if there is no definite boundary between the regions 202 and 201, the regions 201 and 202 can be defined in terms of an opening ratio.

The shielding layer 15 may not be provided between the regions 201 and 202. In this case, the boundary 203 between the regions 202 and 201 is a boundary between the region where the shielding layer 15 is not provided and the region 202.

According to the present exemplary embodiment, the region 202 of the shielding layer 15 is disposed at the position where the signal lines 22 and the insulating member 16 overlap in a planar view, and the region 201 of the shielding layer 15 is disposed at the position where the signal lines 22 and insulating member 16 do not overlap in a planar view. Decreasing the opening ratio of the position where the signal lines 22 and the insulating member 16 overlap with each other in a planar view intensifies the electromagnetic coupling between the signal and the shielding layer 15 in the region overlapping with the insulating member 16 in a planar view. When the signal is sent to the region having the insulating member 16, the electromagnetic field generated by the signal can be deviated in the direction of the shielding layer 15. This reduces the dielectric constant of the region overlapping with the insulating member 16 in a planar view, thus preventing the dielectric loss occurring in the insulating member 16. Increasing the opening ratio of the position where the signal lines 22 and the insulating member 16 do not overlap with each other in a planar view reduces the covered area of the shielding layer 15 in the bending region, making it possible to obtain the favorable flexibility.

The opening ratio of the region 201 is desirably 60% or more, and more desirably 70% or more.

If the opening ratio of the region 201 is less than 60%, the flexibility may possibly be degraded. The opening ratio of the region 202 is desirably 50% or less, and more desirably 40% or less. If the opening ratio of the region 202 exceeds 50%, the electromagnetic field generated by the signal is insufficiently deviated, and the favorable transmission characteristics may not possibly be obtained. However, the present exemplary embodiment is not limited to these opening ratios. The opening ratio of the region 201 needs to be higher than that of the region 202. For example, the opening ratio of the region 202 may be 0%, i.e., the opening 17 may also not be provided.

The boundary 203 between the regions 201 and 202 of the shielding layer 15 is desirably positioned more on the side of the edge surface 170 of the insulating member 16 than the boundary 204 orthogonal to the signal lines 22 out of the edge surfaces of the region 201. The boundary 203 is the position where the region 201 changes to the region 202. Further, the boundary 203 is desirably located at a position of 10% or less of the distance from the edge surface 170 to the boundary 204. This enables more gently changing the impedance of the signal lines 22, providing the favorable transmission characteristics. This also enables improving the opening ratio at the bending portion of the wiring board 200, providing the favorable flexibility. The boundary 204 according to the present exemplary embodiment is the position where the region 201 changes to the region 202 along the X direction from the side of the boundary 203. However, if the region 202 is disposed only on one side of the wiring board 200, the boundary 204 overlaps with an edge of the wiring board 200.

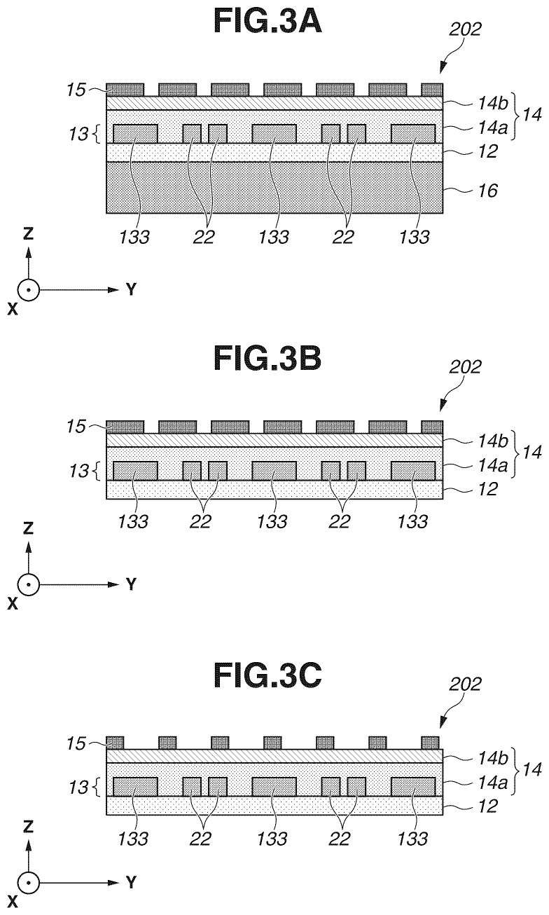

Cross-sections of the wiring board 200 will now be described with reference to FIGS. 3A to 3C. FIG. 3A is a cross-sectional view taken along the A-A line of FIG. 2, FIG. 3B is a cross-sectional view taken along the B-B line of FIG. 2, and FIG. 3C is a cross-sectional view taken along the C-C line of FIG. 2.

The wiring board 200 is formed of a base material (insulating substrate) 12, a coverlay 14 including a bonding layer 14a and a cover layer 14b, a wiring layer 13, and the shielding layer 15 over the entire region in the X direction. The wiring layer 13 includes the above-described plurality of the signal lines 22 and plurality of the ground lines 133. The insulating member 16 is provided under the base material 12 in some regions of the wiring board 200. The base material 12, the coverlay 14, and the insulating member 16 are made of materials having electrical insulation properties. The wiring layer 13 and the shielding layer 15 are made of conductive materials. The base material 12, the coverlay 14, the wiring layer 13, and the shielding layer 15 extend in the X direction. The signal lines 22 and the ground lines 133 configuring the wiring layer 13 are disposed at certain intervals in the Y direction inside the coverlay 14, but do not necessarily need to be disposed inside the coverlay 14.

Referring to FIG. 3A, the region 202 of the shielding layer 15 is disposed at the position where the insulating member 16 overlaps with the signal lines 22 in a planar view. Referring to FIG. 3B, the region 202 of the shielding layer 15 is disposed at the position where the insulating member 16 does not overlap with the signal lines 22 in a planar view. Since the region 202 of the shielding layer 15 is disposed at the position where the insulating member 16 does not overlap with the signal lines 22 in a planar view, the impedance of the signal lines 22 can be more gently changed, providing the favorable transmission characteristics. Referring to FIG. 3C, the region 201 of the shielding layer 15 is disposed at the position where the insulating member 16 does not overlap with the signal lines 22 in a planar view. This increases the opening ratio at the bending portion of the wiring board 200, providing the favorable flexibility.

Desirably, the line width (when viewed from the Z direction) of the shielding layer 15 in the region 201 is smaller than the line width of the shielding layer 15 in the region 202. This makes it easier to adjust the opening ratios of the regions 201 and 202. The line width of the shielding layer 15 in the region 201 is desirably at least 1.5 times the line width of the shielding layer 15 in the region 202, and more desirably at least twice the line width.

Although FIG. 2 illustrates two of the plurality of the signal lines 22, the number of signal lines 22 according to the present exemplary embodiment is not limited to two. The present exemplary embodiment is also applicable to three or more signal lines. The base material 12 and the coverlay 14 are formed in a sheet form. According to the present exemplary embodiment, the bonding layer 14a is disposed between the base material 12 and the cover layer 14b. The bonding layer 14a has a function of bonding the base material 12 and the cover layer 14b. If the coverlay 14 has the bonding function, the bonding layer 14a may be omitted.

Wiring lines used for the signal lines 22 have a bandwidth for enabling transmission of the target digital data signal. To cope with a larger amount of signal transmission, it is preferable to configure differential signal wiring lines forming a pair of the signal lines 22 out of the plurality of the signal lines 22, like the present exemplary embodiment. The plurality of the signal lines 22 may include wiring lines for transmitting single-ended signals such as control signals and response signals.

If a positive-phase signal and a negative-phase signal having different electrical average lengths are transmitted in the differential signal wiring lines, mode conversion occurs in which a part of the differential signal changes to a common-mode signal, inducing common-mode noise. If common-mode noise resonates on the wiring board 200, large-radiated noise occurs with the frequency of common-mode noise. With the recent increase in the amount of communication data, a differential signal having a high transmission rate of, for example, 5 Giga bits per second (Gbps) or higher is transmitted in differential signal wiring lines. A relation R=2f is established between the transmission rate R [bps] and the fundamental frequency f [Hz] of the signal. Variations of the current flowing in the transmission line generally increase over time, and thus the amount of radiated noise occurring increases with increasing frequency of the transmitted signal. Since occurring radiated noise is close to the communication frequency bandwidth of a wireless communication apparatus, the radiated noise may be superimposed on communicated data when a wireless communication integrated circuit (IC) wirelessly communicates with an external apparatus (e.g., a personal computer (PC) and a wireless router) via an antenna. Thus, providing the regions 201 and 202 like the present exemplary embodiment enables implementing the wiring board 200 that satisfies both the flexibility and the high-frequency signal transmission characteristics.

The interval between the signal lines 22 is desirably larger than the distance between the signal lines 22 and the shielding layer 15. In the region where the insulating member 16 is formed, the electromagnetic field generated by the signal can thereby be more deviated in the direction of the shielding layer 15, and the favorable transmission characteristics can be obtained. The plurality of the signal lines 22 may include wiring lines for transmitting single-ended signals such as control signals and response signals. The distance between the signal lines 22 refers to the distance between the signal lines 22 in a pair when the signal lines 22 serve as differential signal wiring lines.

The method for forming the signal lines 22 is not particularly limited, but the signal lines 22 can be formed by such methods as metal foil lamination, metal plating, and ink-jet process. If a copper foil is used as a metal foil, a transmission line pattern to be used in the photo-lithographic etching process can be formed using a film formed of laminated copper foil. If the ink-jet process is used, a transmission line pattern can be formed by drawing the pattern with high polymer ink containing metal particles and burning the pattern at a temperature equal to or lower than the glass transition point (Tg) of the base material 12. The thickness of the signal lines 22 is not particularly limited but desirably 0.1 μm (micrometers) or more and 20 μm or less.

A configuration of the wiring board 200 will now be described in more detail.

A plastic and/or an insulating resin is applicable to the insulating member 16. Examples of plastics include epoxy-based resins, imide-based resins, phenol-based resins, and cyanate-based resins. The insulating member 16 may contain fillers. Examples of fillers to be contained include silica, kaolin, talc, alumina, and a combination of them. In addition to fillers, fibers can be used. Examples of applicable fibers include glass cloths using glass fiber bundles, carbon fiber bundles, polyester fiber bundles, nylon fiber bundles, and aramid fiber bundles. The method of forming the insulating member 16 below the base material 12 is not particularly limited but a bonding layer (not illustrated) is used. Examples of bonding layers include an adhesive agent and an adhesive film. Examples of applicable adhesives include acrylic resin, urethane resin, polyester resin, polyamide resin, ethylene butyl alcohol resin, ethylene-vinyl acetate copolymer, and polyvinyl chloride acetate copolymer. Examples of applicable methods for forming a bonding layer include regular printing methods (e.g., offset printing, gravure printing, and screen printing) and coating methods (e.g., photogravure coating method, roll coating method, and comma coating method). An adhesive film can be used as the bonding layer by laminating the adhesive film under the base material 12. Adhesive films can be laminated with the dry laminate method using, for example, a non-drawn polypropylene film. The thickness of the insulating member 16 in the Z direction is desirably 20 μm or more to provide a sufficient strength for the connector to be attached and detached. The insulating member 16 desirably has a hardness (Young's modulus) enough to reinforce the wiring board 200 and has a flexibility lower than that of the wiring board 200. The Young's modulus of the insulating member 16 is desirably higher than those of the base material 12, the bonding layer 14a, the cover layer 14b, and the shielding layer 15 configuring the wiring board 200. The thickness of the insulating member 16 is desirably larger than those of the base material 12 and shielding layer 15, but the present exemplary embodiment is not limited thereto.

The shielding layer 15 is disposed above the coverlay 14. The manufacturing method of the shielding layer 15 is not particularly limited, but direct patterning is desirably performed by any other various printing method, such as the screen-printing method, and the ink-jet printing method. Alternatively, a conductive film may be subjected to patterning by using the photo-lithographic etching process. The shielding layer 15 may also be pre-processed into a predetermined shape by using die-cut processing or braided laces and then directly bonded.

Examples of methods for forming the shielding layer 15 on the coverlay 14 include the subtractive method, electroless plating method, electrolytic plating method, and physical evaporation methods (e.g., vacuum evaporation method and sputtering method). A method for laminating conductive fibers or the screen-printing method can also be applicable. Examples of metals configuring the shielding layer 15 include copper, aluminum, nickel, iron, gold, silver, platinum, tungsten, chromium, titanium, tin, lead, and palladium. One of these metals or a combination of two or more of them is also applicable. Of these, silver or copper is preferable from the viewpoint of conductivity and cost reduction.

The thickness of the shielding layer 15 is desirably 1 μm or more, and more desirably 5 μm or more. If the thickness is less than 1 μm, there may be an insufficient bending resistance. If the thickness of the shielding layer 15 is 20 μm or less, the thickness of the wiring board 200 can also be reduced, making it possible to provide a wiring board 200 having high flexibility. The surface resistance value of the shielding layer 15 is desirably 1 ohm/sq. or less, and more desirably 0.1 ohms/sq. or less.

The shielding layer 15 according to the present exemplary embodiment has a plurality of openings continuously disposed in a predetermined direction. The shapes of the openings are not particularly limited. The openings can be formed in any shape as desired, such as rhombus, eclipse, rectangle, hexagon, and a slit extending in the Y direction. Of these shapes, a plurality of shapes may be selected and arranged, and polygons, such as quadrangle and hexagon, are preferable. If the openings have a polygon shape, variations in the width of non-opening portions can be restrained, making a uniform return path of radiated noise and efficiently restricting radiated noise.

The base material 12, the bonding layer 14a, and the cover layer 14b will be described in detail below.

The material of the base material 12 as an insulating substrate is desirably a resin. Examples of applicable resins include polyimide-based resins (e.g., polyimide, polyamide, and polyamide-imide), thermosetting resins (e.g., epoxy), and thermoplastic resins (e.g., liquid crystal polymer). Of these resins, polyimide and liquid crystal polymer are preferable. Polyimide is superior in the heat resistance and mechanical characteristics and is easily commercially available. Liquid crystal polymer has a low dielectric constant and is preferable for high-speed signal transmission applications. Liquid crystal polymer also has low absorbency and is superior in dimensional stability.

The thickness of the base material 12 is not particularly limited and is desirably 10 μm or more and 100 μm or less. If the thickness is less than 10 μm, the distance between the signal lines 22 and the shielding layer 15 is short, possibly resulting in an excessive increase in the characteristic impedance value. In contrast, if the thickness exceeds 100 μm, the rigidity of the resin increases, possibly resulting in insufficient flexibility. The thickness is more desirably 12 μm or more and 75 μm or less.

The bonding layer 14a will now be described in detail. The bonding layer 14a is disposed between the base material 12 (insulating substrate), the cover layer 14b, and the signal lines 22. More specifically, the bonding layer 14a is a hardened material of an adhesive. The bonding layer 14a desirably has high electrical insulation properties. Examples of adhesives used for forming the bonding layer 14a include acrylonitrile-butadiene rubber (NBR)-based adhesives, polyamide-based adhesives, polyester-based adhesives, acrylic-based adhesives, polyester polyurethane-based adhesives, and silicone-based adhesives.

Desirably, the bonding layer 14a can sufficiently cover the signal lines 22 as transmission lines and is smooth. The thickness of the bonding layer 14a in the Z direction is desirably 2 μm or more and 50 μm or less. If the thickness of the bonding layer 14a is 2 μm or more, the adhesive is sufficiently embedded between the signal lines 22 enabling firm bonding by the bonding layer 14a. If the thickness of the bonding layer 14a is 50 μm or less, the adhesive can be prevented from laterally exuding from between the base material 12 and the cover layer 14b. From the above-described viewpoint, the thickness of the bonding layer 14a in the Z direction is desirably 5 μm or more and 30 μm or less.

The method for forming the bonding layer 14a is not particularly limited. Examples of the methods include a method for curing the layer by laminating a sheet-like adhesive and a method for curing the layer by applying a liquid adhesive by using a dispenser or printing method and then curing the layer with heat or ultraviolet ray.

The cover layer 14b will now be described in detail. Plastics and/or insulating resins are applicable as the cover layer 14b. Plastics used for the cover layer 14b include what is called engineering plastics. Other examples of plastics used for the cover layer 14b include polypropylene, crosslinked polyethylene, polyester, polybenzimidazole, polyamide, polyimide, polyimide amide, and polyetherimide. Examples of plastics used for the cover layer 14b include polyphenylene sulfide (PPS), polyethylenenaphthalate (PEN), and polyetheretherketone (PEEK). From the viewpoint of cost reduction, the use of a polyester film is preferable. From the viewpoint of the superiority in flame resistance, a polyphenylene sulfide film is desirably used. Further, if the heat resistance is desired, the use of an aramid film or a polyimide film is preferable.

Examples of insulating resins used for the cover layer 14b include resins having electrical insulation properties, such as thermosetting resins and ultraviolet-curable resins. Examples of thermosetting resins include phenol resin, acrylic resin, epoxy resin, melamine resin, silicone oil, and acrylic denaturation silicone resin. Examples of ultraviolet-curable resins include epoxy acrylate resin, polyester acrylate resin, and methacrylate denaturation products of these resins. Applicable curing forms include heat curing, ultraviolet curing, and electron beam curing. Further, other additives may be mixed as desired, such as color pigment, flame retardant, antioxidant, lubricant, dust removing inhibitor, and curing accelerator.

Although the method for forming the cover layer 14b is not particularly limited, the bonding layer 14a can be coated with the cover layer 14b by using the following methods. Examples of methods for applying a solution with an insulating resin dissolved in a solvent include the gravure coating method, kiss coating method, die coating method, blade coating method, roll coating method, knife coating method, spray coating method, bar coating method, spin coating method, and dip coating method. A solvent can be suitably selected according to the type of the resin to be used.

Examples of applicable solvents include ketone-based solvents, such as acetone, methyl ethyl ketone, and cyclohexanone, and alcohol-based solvents such as methanol, ethanol, propanol, ethylene glycol, glycerine, and propylene glycol monomethyl ether. Other examples of applicable solvents include acids, such as acetic acid, amide-based solvents, such as formamide, dimethylacetamide, and N-methylpyrrolidone, nitrile-based solvents, such as acetonitrile and propyro nitriles, and ester-based solvents, such as methyl acetate and ethyl acetate. Other examples of applicable solvents include carbonate-based solvents, such as dimethyl carbonate and diethyl carbonate. To make the solvent volatilize as desired during coating, a heating or drying process may be provided. For heating and drying, a heating apparatus and a drying apparatus such as a hot air drier and an infrared heater can be used. The heating temperature, drying temperature, heating time, and drying time can be suitably selected.

Desirably, the thickness of the cover layer 14b in the Z direction is 5 μm or more and 50 μm or less. If the thickness of the cover layer 14b in the Z direction is 5 μm or more, sufficient strength of the cover layer 14b can be ensured. If the thickness of the cover layer 14b in the Z direction is 50 μm or less, the slidability and flexibility improve. From the above-described viewpoints, the thickness of the cover layer 14b in the Z direction is more desirably 10 μm or more and 30 μm or less. The specific volume resistance of the cover layer 14b is desirably 10⁹ Ω·cm (ohms centimeter) or more, and more desirably 10¹³ Ω·cm or more.

### EXEMPLARY EMBODIMENTS

The present disclosure will now be described in more detail with reference to exemplary embodiments and comparative examples. However, the present disclosure is not limited to the following exemplary embodiments. The method for evaluating (measuring) the wiring boards according to the present disclosure will be described below.

The method for evaluating the wiring boards according to the exemplary embodiments and comparative examples will be described below.

### (1) Evaluation of Transmission Characteristics (Eye Pattern)

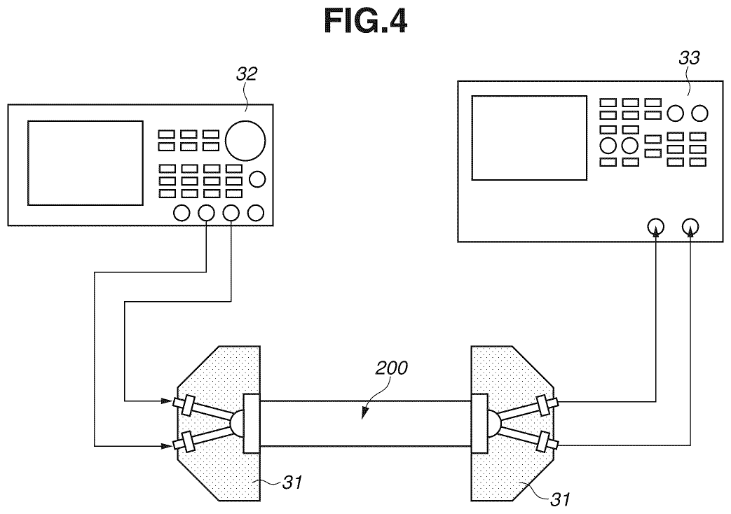

We evaluated the output waveform characteristics of the flexible printed wiring board by using the system configuration illustrated in FIG. 4. This system includes a pair of connection boards 31, a signal generator 32, and an oscilloscope 33. The M8041A from Agilent Technologies was used as the signal generator 32. The 92504A from Agilent Technologies was used as the oscilloscope 33. Each of the connection boards 31 is provided with an input and an output terminals. The wiring board 200 to be subjected to measurement was connected between the pair of the connection boards 31, being floated in mid air in a straight-line state. Further, one connection board 31 was connected with the signal generator 32, and a pseudo random signal of Pseudo-Random Binary Sequence (PRBS) 23 was input at a bit rate of 10.6 Gbps. The magnitude of the input signal assumed is 250 mV/side (with a differential voltage of 500 mV (millivolts)). The other connection board 31 was connected with the oscilloscope 33, and the opening amplitude of the signal eye pattern output from the connection board 31 was measured. The measurement was performed in atmosphere at a temperature of 25° C. (Celsius) and a relative humidity of 30% to 50%. Evaluation criteria are as follows:
A (Excellent): An opening amplitude of 120 mV or more
B (Good): An opening amplitude of 90 mV or more and 120 mV or less
C (Disapproved): An opening amplitude of less than 90 mV

### (2) Bending Load Measurement

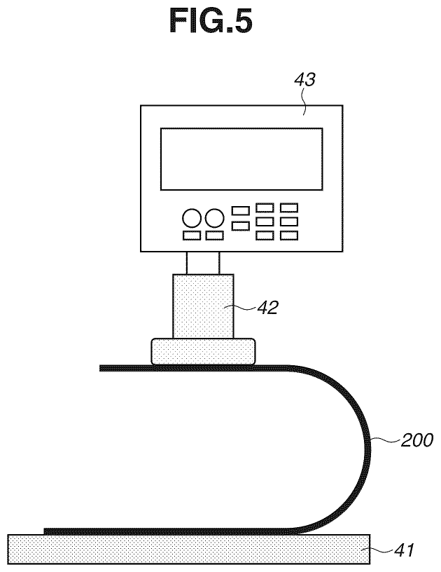

As illustrated in FIG. 5, the wiring board 200 was placed on a stainless steel plate 41 with a thickness of 1 mm, and then bent with a bending radius of 3 mm so that the bending line becomes parallel to the board width direction. A force measurement device 42 (ZTS-2N from IMADA Co., Ltd.) was pressed onto the wiring board 200, and then the bending load was measured at the moment. The evaluation criteria are as follows:
A (Excellent): A bending load of less than 10 gf (gram force)
B (Good): A bending load of 10 gf or more and 15 gf or less
C (Disapproved): A bending load of 15 gf or more

### First Exemplary Embodiment

We manufactured the wiring board 200 illustrated in FIG. 2. A polyimide film (Kapton 100H from Toray Du Pont) with a thickness of 25 μm was prepared as the base material 12. A copper foil with a thickness of 12 μm was laminated as the wiring layer 13 on the base material 12, and the signal lines 22 and the ground lines 133 with a total length of 100 mm were formed using the etching technique. A pair of the signal lines 22 was formed as a pair of differential signal wiring lines, with a 55 μm distance between the signal lines 22 and a 205 μm width of the pair of the signal lines 22.

In contrast, the wiring layer 13 was obtained by disposing a ground line 133 with a width of 100 μm on both sides of a pair of the signal lines 22, at the position of 150 μm in the interval between adjacent signal lines 22. From the viewpoint of insulation properties of the signal lines 22, the base material 12 was prepared such that the ground lines 133 positioned at both edges of the wiring board 200 are inwardly disposed by 500 μm from the outer side of the wiring board 200.

Next, the coverlay 14 was formed on the wiring layer 13. The bonding layer 14a was formed by using an adhesive with a thickness of 25 μm, and the cover layer 14b was formed by using a coverlay (CEAM0525KA from Arisawa Manufacturing Co., Ltd.) with a thickness of 15 μm, resulting in a total thickness of 37.5 μm. The shielding layer 15 was then formed on the coverlay 14. The shielding layer 15 was formed by printing a silver paste (DD-1630L-245 from Kyoto Elex Co., Ltd.) to achieve a thickness of 5 μm by using a screen printer (MT-320T from Micro-tec Co., Ltd.). In this case, the shielding layer 15 was formed by adjusting the opening patterns of the screen-printing plate to print two different patterns for the regions 201 and 202. The boundary 203 between the regions 201 and 202 was set to be positioned more on the side of the boundary 204 by 5 mm than the edge surface 170 of the insulating member 16 intersecting with the signal lines 22 in a pattern planar view. The region more on the side of the boundary 204 than the boundary 203 is the region 201, and the region on the side opposite to the boundary 204 is the region 202. The region 201 was formed in a rhombus mesh pattern with a line width of 58 μm. Each opening 17 has a length of 2,000 μm in the X direction and a length of 500 μm in the Y direction. The longitudinal direction of the opening 17 is parallel to the signal lines 22. The region 202 was formed in a rhombus mesh pattern with a line width of 200 μm. Each opening 17 has a length of 2,000 μm in the X direction and a length of 500 μm in the Y direction. The longitudinal direction of the opening 17 is parallel to the signal lines 22. Eventually, the insulating member 16 was formed by bonding a reinforcing plate (FR-4 formed of glass epoxy with a thickness of 400 μm and an adhesive with a thickness of 60 μm) below the base material 12 for up to the 20 mm position in the X direction. Thus, the wiring board 200 according to the first exemplary embodiment was obtained.

### Second Exemplary Embodiment

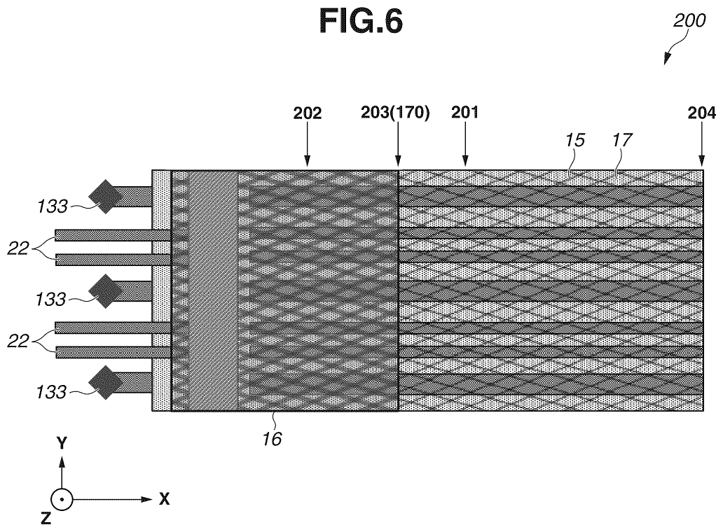

As illustrated in FIG. 6, the boundary 203 between the regions 201 and 202 of the shielding layer 15 was formed so as to overlap with the edge surface 170 of the insulating member 16 intersecting with the signal lines 22 in a pattern planar view. Other portions were formed in a similar way to the first exemplary embodiment. Thus, the wiring board 200 according to a second exemplary embodiment was obtained.

### Third Exemplary Embodiment

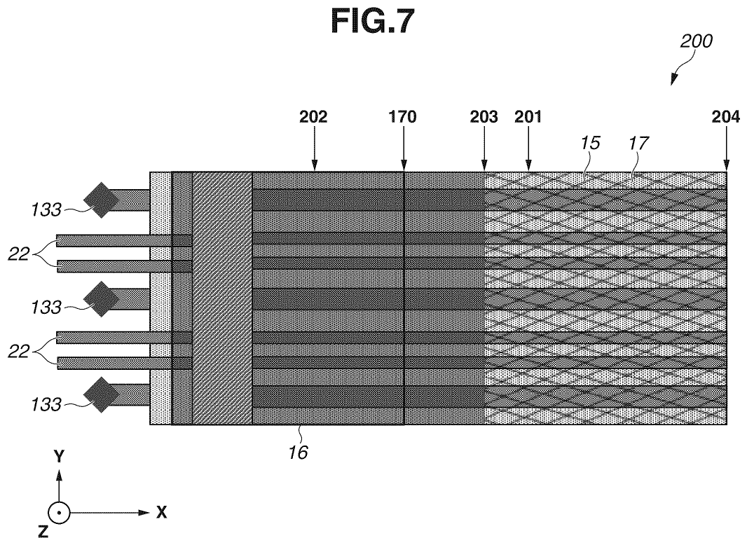

As illustrated in FIG. 7, the region 202 of the shielding layer 15 was formed in a solid pattern without the openings 17. Other portions were formed in a similar way to the first exemplary embodiment. Thus, the wiring board 200 according to a third exemplary embodiment was obtained.

### Fourth Exemplary Embodiment

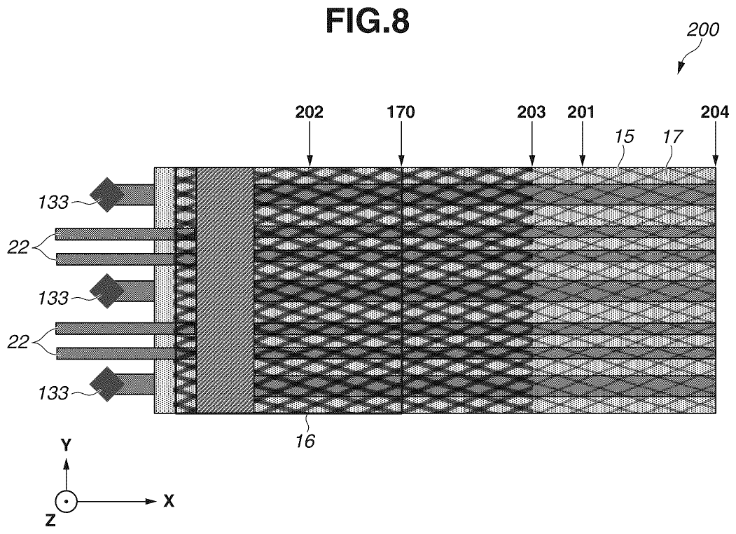

As illustrated in FIG. 8, the boundary 203 between the regions 201 and 202 of the shielding layer 15 was formed more on the side of the boundary 204 by 8 mm than the edge surface 170 of the insulating member 16. Other portions were formed in a similar way to the first exemplary embodiment. Thus, the wiring board 200 according to a fourth exemplary embodiment was obtained.

### Fifth Exemplary Embodiment

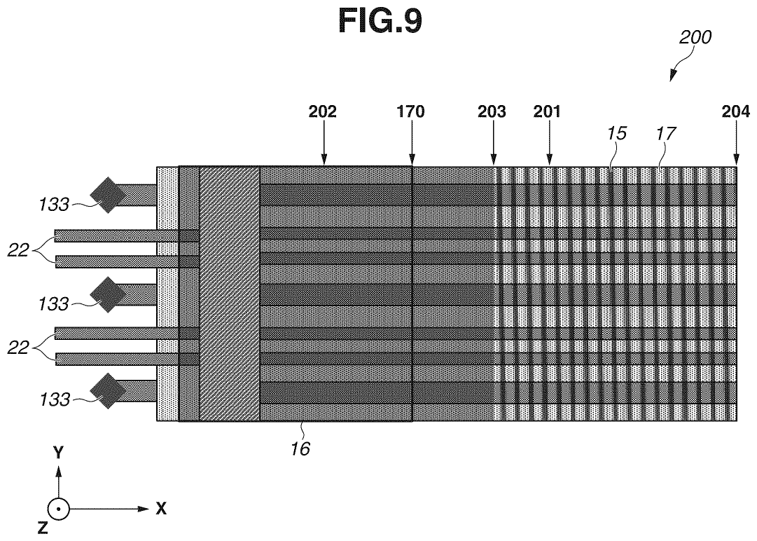

As illustrated in FIG. 9, the region 201 of the shielding layer 15 was formed in a stripe pattern in parallel with the Y direction, with a line width of 50 μm and a line interval of 200 μm, and the region 202 of the shielding layer 15 was formed in a solid pattern without the openings 17. Other portions were formed in a similar way to the first exemplary embodiment. Thus, the wiring board 200 according to a fifth exemplary embodiment was obtained.

### Sixth Exemplary Embodiment

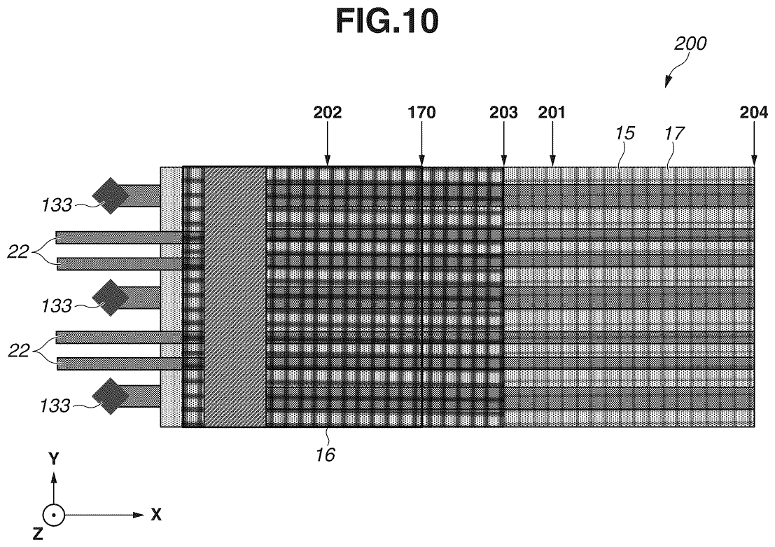

As illustrated in FIG. 10, the region 201 of the shielding layer 15 was formed in a square mesh pattern with a line width of 50 μm and a length of one side of the opening 17 of 425 μm, and the region 202 of the shielding layer 15 was formed in a square mesh pattern with a line width of 176 μm and a length of one side of the opening 17 of 425 μm. Other portions were formed in a similar way to the first exemplary embodiment. Thus, the wiring board 200 according to a sixth exemplary embodiment was obtained.

### Seventh Exemplary Embodiment

The opening ratio of the region 202 was set to 70%. Other portions were formed in a similar way to the first exemplary embodiment. Thus, the wiring board 200 according to a seventh exemplary embodiment was obtained.

### Eighth Exemplary Embodiment

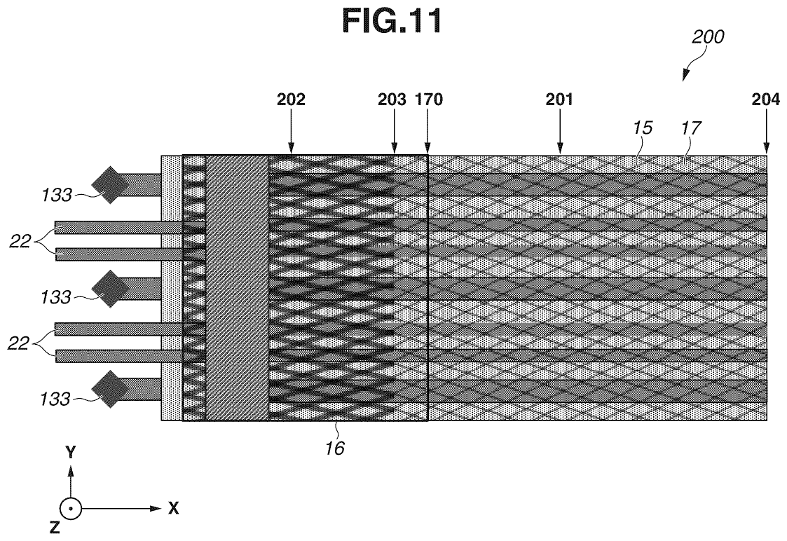

As illustrated in FIG. 11, the boundary 203 between the regions 201 and 202 of the shielding layer 15 was formed more on the side opposite to the boundary 204 by 5 mm than the edge surface 170 of the insulating member 16. Other portions were formed in a similar way to the first exemplary embodiment. Thus, the wiring board 200 according to an eighth exemplary embodiment was obtained.

### First Comparative Example

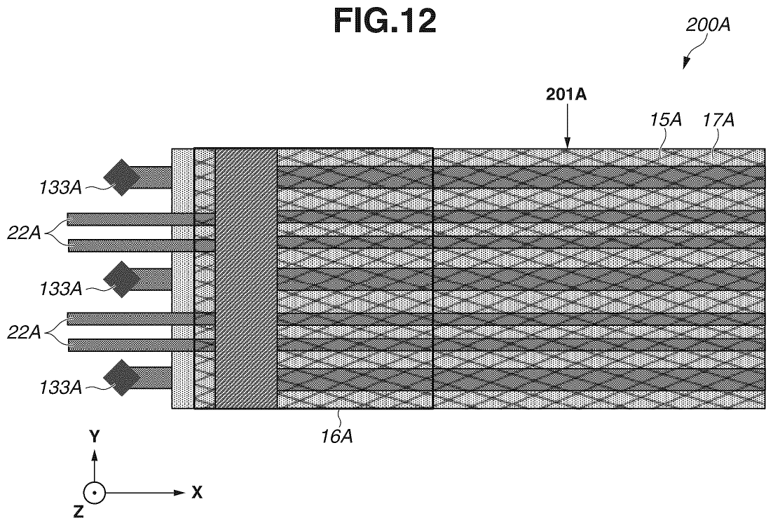

As illustrated in FIG. 12, for the entire range of a shielding layer 15A, a region 201A was formed in a rhombus mesh pattern with a line width of 58 μm. Each opening 17A has a length of 2,000 μm in the X direction and a length of 500 μm in the Y direction. An insulating member 16A was formed so as to overlap with a part of the region 201A in a planar view. The longitudinal direction of the opening 17A is parallel to signal lines 22A and ground lines 133A. Other portions were formed in a similar way to the first exemplary embodiment. Thus, a wiring board 200A according to a first comparative example was obtained.

### Second Comparative Example

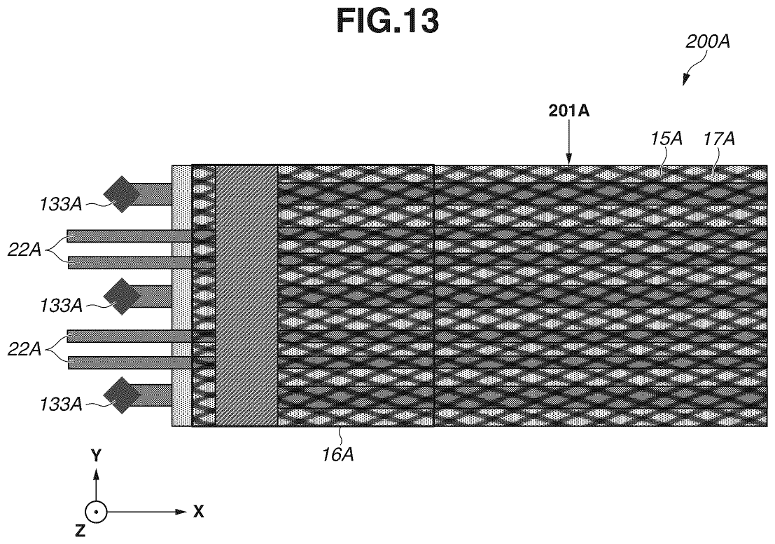

As illustrated in FIG. 13, for the entire range of a shielding layer 15A, a region 201A was formed in a rhombus mesh pattern with a line width of 200 μm. Each opening 17A has a length of 2,000 μm in the X direction and a length of 500 μm in the Y direction. The insulating member 16A was formed so as to overlap with a part of the region 201A in a planar view. The longitudinal direction of the opening 17A is parallel to the signal lines 22A and the ground lines 133A. Other portions were formed in a similar way to the first exemplary embodiment. Thus, a wiring board 200A according to a second comparative example was obtained.

### (Evaluation Results)

Evaluation results for the first to the eighth exemplary embodiments and the first and the second comparative examples will be described in Table 1. The wiring board 200 according to the first to the eighth exemplary embodiments provides the favorable transmission characteristics and flexibility.

When the first and the second exemplary embodiments are compared, the boundary 203 between the regions 201 and 202 according to the first exemplary embodiment is disposed more on the side of the boundary 204 than that according to the second exemplary embodiment. Thus, more gently changing the impedance of the signal lines 22 enables restricting the signal reflection loss, obtaining more favorable transmission characteristics. When the first and the fourth exemplary embodiments are compared, the first exemplary embodiment provides higher flexibility than that of the fourth exemplary embodiment. This is because the boundary 203 according to the fourth exemplary embodiment is positioned more on the side of the boundary 204 than that according to the first exemplary embodiment. Thus, shifting the boundary 203 toward the side of the boundary 204 increases the covered area of the shielding layer 15 at the bending portion, thus degrading the flexibility.

According to the first comparative example, the shielding layer 15 was formed in a rhombus mesh pattern with an entirely uniform opening ratio of 80%. This configuration causes insufficient deviation of the signal electromagnetic field by the shielding layer 15 as described above, and excessively increases the dielectric loss in the region of the insulating member 16, thus degrading the transmission characteristics. According to the second comparative example, the shielding layer 15 was formed in a rhombus mesh pattern with an entirely uniform opening ratio of 50%. This configuration not only increases the covered area of the shielding layer 15 to degrade the flexibility but also excessively increases the deviation of the signal electromagnetic field over the entire signal wiring range to increase the resistance loss, thus degrading the transmission characteristics.

TABLE 1

| | | First | Second | Third | Fourth | Fifth |
|---|---|---|---|---|---|---|
| | | exemplary | exemplary | exemplary | exemplary | exemplary |
| | | embodiment | embodiment | embodiment | embodiment | embodiment |
| Region 201 | Configuration | Rhombus | Rhombus | Rhombus | Rhombus | Slit |
| | | mesh | mesh | mesh | mesh | |
| | Opening ratio | 80 | 80 | 80 | 80 | 80 |
| Region 202 | Configuration | Rhombus | Rhombus | Solid | Rhombus | Solid |
| | | mesh | mesh | | mesh | |
| | Opening ratio | 50 | 50 | 0 | 50 | 50 |
| Distance between edge surface | | 5 | 0 | 5 | 8 | 5 |
| 160 and boundary 203 [mm] | | | | | | |
| Opening amplitude [mV] | | 141 | 128 | 125 | 134 | 122 |
| | | A | A | A | A | A |
| Flexibility [gf] | | 9.1 | 8.3 | 9.2 | 13.2 | 8.9 |
| | | A | A | A | B | A |
| | | Sixth | Seventh | Eighth | First | Second |
| | | exemplary | exemplary | exemplary | comparative | comparative |
| | | embodiment | embodiment | embodiment | example | example |
| Region 201 | Configuration | Square | Rhombus | Rhombus | Rhombus | Rhombus |
| | | mesh | mesh | mesh | mesh | mesh |
| | Opening ratio | 80 | 80 | 80 | 80 | 50 |
| Region 202 | Configuration | Square | Rhombus | Rhombus | Rhombus | Rhombus |
| | | mesh | mesh | mesh | mesh | mesh |
| | Opening ratio | 50 | 70 | 50 | 80 | 50 |

| Distance between edge surface | 5 | 5 | −5 | — | — |
|---|---|---|---|---|---|
| 160 and boundary 203 [mm] | | | | | |
| Opening amplitude [mV] | 138 | 105 | 90 | 82 | 74 |
| | A | B | B | C | C |
| Flexibility [gf] | 9 | 8.8 | 8.3 | 8.3 | 17.6 |
| | A | A | A | A | C |

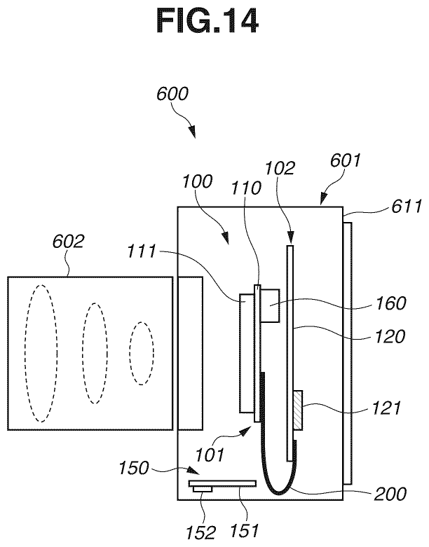

A digital camera 600 (imaging apparatus) as an example of an electronic apparatus using either one of the wiring boards according to the first exemplary embodiment will be described with reference to FIG. 14.

The digital camera 600, which is a lens-exchangeable digital camera, has a camera body 601. A lens unit (lens barrel) 602 including lenses is attachable to and detachable from the camera body 601. The camera body 601 includes a housing 611, an electronic unit 100, and a wireless communication unit 150. The electronic unit 100 and the wireless communication unit 150 are stored in the housing 611. With an imaging apparatus, the electronic unit 100 is an imaging unit.

The electronic unit 100 includes circuit boards 101 and 102, and a wiring board 200 for electrically connecting the circuit boards 101 and 102. The circuit board 101 is an example of a first circuit board. The circuit board 102 is an example of a second circuit board. Using the wiring board 200 to connect the circuit boards 101 and 102 can lead to a lighter wiring structure than that of a coaxial cable. The above-described wiring board according to the first exemplary embodiment is used as the wiring board 200.

The circuit board 101 includes the wiring board 110 and a semiconductor apparatus 111 mounted on the wiring board 110. The circuit board 102 includes a wiring board 120 and a semiconductor apparatus 121 mounted on the wiring board 120. The semiconductor apparatuses 111 and 121 are examples of electronic components mounted on the wiring boards 110 and 120, respectively. Examples of electronic components mounted on the wiring boards 110 and 120 include an imaging apparatus, calculation apparatus, display apparatus, communication apparatus, storage device, power source apparatus, and calculation apparatus. Electronic components mounted on the wiring boards 110 and 120 may be not only active components but also passive components.

The semiconductor apparatus 111 is an image sensor (imaging apparatus) according to the second exemplary embodiment. Examples of image sensors include a complementary metal oxide semiconductor (CMOS) image sensor and a charge coupled device (CCD) image sensor. The image sensor has a function of converting light incident via the lens unit 602 into an electrical signal. According to the second exemplary embodiment, the semiconductor apparatus 121 is a processor (calculation apparatus), such as a digital signal processor and an image signal processor. The image signal processor has a function of acquiring an electrical signal indicating image data from the semiconductor apparatus 111 as an image sensor (imaging apparatus), correcting the acquired electrical signal, and generating and outputting the corrected image data. A product in which the circuit board 101 connected with the wiring board 200 includes an image sensor can be referred to as an imaging module or an imaging unit. The imaging module is an example of the electronic module 10, and the imaging unit is an example of the electronic unit 100.

According to the present exemplary embodiment, the electronic unit 100 includes a driving apparatus 160 for moving the circuit board 101 (the wiring board 110 and the semiconductor apparatus 111). The driving apparatus 160 includes a motor as an example of a driving source. The digital camera 600 including the electronic unit 100 having the driving apparatus 160 enables implementing a camera shake correction (image stabilization) function by moving the semiconductor apparatus 111 via the circuit board 101. The driving source in the driving apparatus 160 is not limited to an electromagnetic motor but may be a piezoelectric motor, such as an ultrasonic motor, and an electrostatic motor. As described above, the wiring board 200 is connected to the moving circuit board 101 and thus flexibility is desired.

Instead of the electronic unit 100 including the wiring board 200 and the circuit boards 101 and 102, a product including either one of the circuit boards 101 and 102, the driving apparatus 160, and other components can be referred to as an electronic unit.

According to the present exemplary embodiment, the wiring board 200 is mounted on the digital camera 600 in a bent state and disposed such that the side of the shielding layer 15 is the outer side of the curved surface. In other words, the shielding layer 15 is equivalent to the surface on the side of the housing 611.

The wireless communication unit 150 is a modularized unit for performing wireless communication in the GHz bandwidth. The wireless communication unit 150 includes a rigid wiring board as an example of the wiring board 151 including an antenna (not illustrated), and a wireless communication IC 152 mounted on the wiring board 151. The antenna is provided on the same plane as the wireless communication IC 152 and disposed at a position close to the housing 611 to facilitate communication with an external apparatus. The wireless communication IC 152 wirelessly communicates with an external apparatus, such as a personal computer (PC) and a wireless router via the antenna, it is thus desirable to be capable of transmitting and/or receiving image data. According to the present exemplary embodiment, the wireless communication IC 152 enables data transmission and reception via the antenna. More specifically, the wireless communication IC 152 modulates a digital signal indicating image data acquired from the semiconductor apparatus 121 and transmits the signal as an electric wave having a wireless standard communication frequency from the antenna. The wireless communication IC 152 demodulates the electric wave received by the antenna into a digital signal indicating image data. The wireless communication IC 152 wirelessly communicates with, for example, an external apparatus according to the Wi-Fi® or Bluetooth® standard. If the shielding layer 15 disposed on the wiring board 200 in the electronic unit 100 as an imaging unit is used as an electromagnetic shield, it is possible to prevent the electronic unit 100 from generating noise due to the electromagnetic wave emitted from the wireless communication unit 150. The wiring board 200 can also be used to connect the wiring board 151 and other wiring boards.

To bond a flexible wiring board and a rigid substrate in a small area, solder-based direct bonding is performed. Japanese Patent Application Laid-Open No. 2018-200779 discloses a flexible cable for facilitating direct bonding through a shielding layer with a mesh structure. However, only a shielding layer with a mesh structure discussed in Japanese Patent Application Laid-Open No. 2018-200779 causes the deformation of the terminal portion as a bonding portion, making it difficult to align the terminal with lands and conductor patterns on a rigid substrate, possibly resulting in defective bonding. A third exemplary embodiment provides a flexible wiring board in which defective bonding is not easily generated.

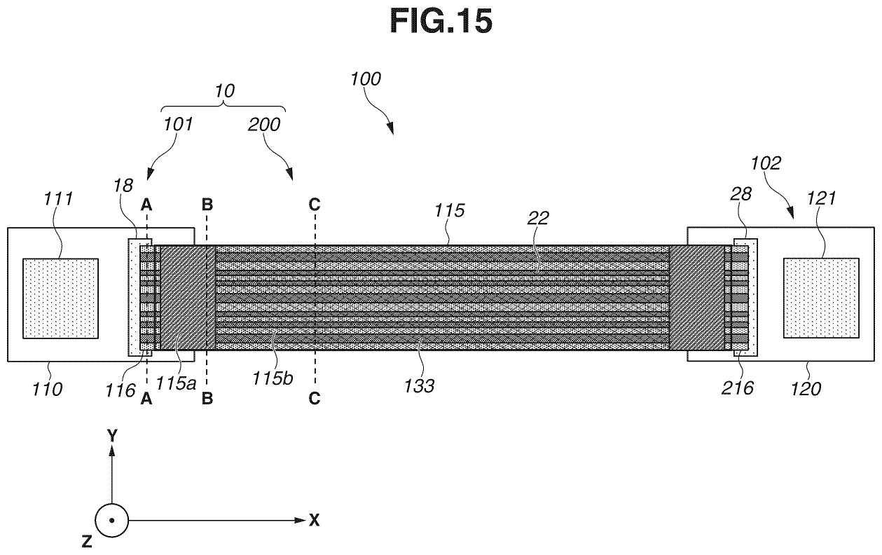

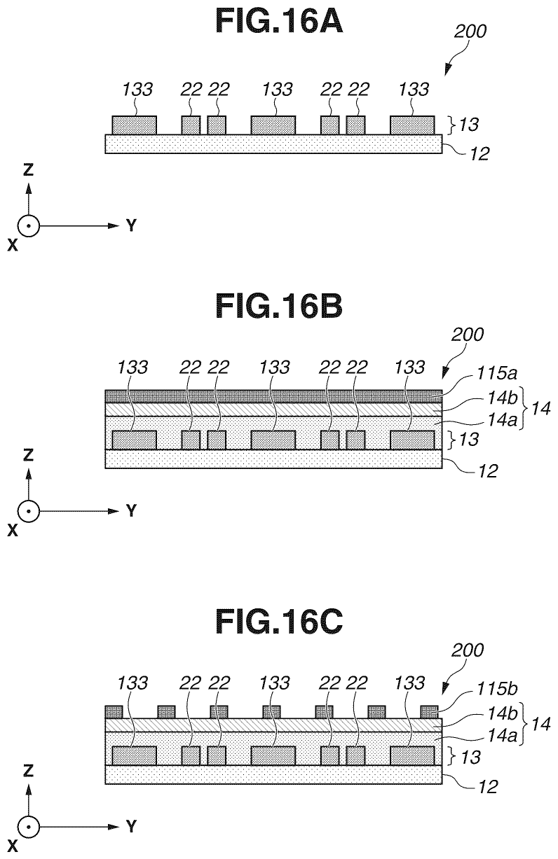

The third exemplary embodiment will be described below with reference to FIGS. 15 and 16. The following description will be made centering on differences from the first exemplary embodiment. The description of configurations assigned common reference numerals will be suitably omitted. With the electronic unit 100 according to the third exemplary embodiment, the connector 112 is not mounted on the wiring board 110 configuring the circuit board 101, and the connector 122 is not mounted on the wiring board 120 configuring the circuit board 102. Thus, the present exemplary embodiment does not include the insulating member 16 disposed around the connector 112 of the wiring board 200 according to the first exemplary embodiment.

The wiring board 110 configuring the circuit board 101 has a conductor pattern 18 electrically connected with the semiconductor apparatus 111. The material of the conductor pattern 18 is not particularly limited. Examples of applicable materials include metals such as gold, copper, and silver, and conductive oxides. The conductor pattern 18 is electrically connected with a terminal portion 116 of the wiring board 200 (described below) by a conductive bonding material (not illustrated).

Examples of conductive bonding materials include solder and conductive resins.

Like the wiring board 110, the wiring board 120 configuring the circuit board 102 has a conductor pattern 28 electrically connected with the semiconductor apparatus 121. The material of the conductor pattern 28 is not particularly limited. Examples of applicable materials include metals such as gold, copper, and silver, and conductive oxides. The conductor pattern 28 is electrically connected with a terminal portion 216 of the wiring board 200 by a conductive bonding material (not illustrated). Examples of conductive bonding materials include solder and conductive resins.

The wiring board 200 according to the third exemplary embodiment will now be described with reference to FIGS. 15 and 16A to 16C. FIG. 16A is a cross-sectional view illustrating the wiring board 200 taken along the A-A line of FIG. 15. FIG. 16B is a cross-sectional view illustrating the wiring board 200 taken along the B-B line of FIG. 15. FIG. 16C is a cross-sectional view illustrating the wiring board 200 taken along the C-C line of FIG. 15.

### <Configuration of Wiring Board>

The wiring board 200 according to the third exemplary embodiment is formed of the base material 12 as an insulating substrate, the wiring layer 13 having the signal lines 22, and the coverlay 14 including the bonding layer 14a and the cover layer 14b as insulation layers, which are laminated in this order. The wiring board 200 is formed of the terminal portion 116 as a connection point with the conductor pattern 18 of the circuit board 101 and a reinforcing layer 115 adjacent to the terminal portion 116 portion that are disposed in this order in the X direction (first direction) in which the signal lines 22 extend. The reinforcing layer 115 is formed of a first reinforcing portion 115a adjacent to the terminal portion 116 and a second reinforcing portion 115b adjacent to the first reinforcing portion 115a that are disposed in this order. More specifically, the wiring board 200 according to the third exemplary embodiment differs from that according to the first exemplary embodiment in that the reinforcing layer 115 is provided instead of the shielding layer 15.

The reinforcing layer 115 has a function of preventing a swelling of the terminal portion 116 of the wiring board 200 and a function of protecting the wiring board 200. Using a conductive material for the reinforcing layer 115 allows the reinforcing layer 115 to have a function as a shielding member. More specifically, the reinforcing layer 115 shields electromagnetic interference (EMI) due to radiated noise caused by the electromagnetic radiation generated from the signal lines 22.

Examples of materials configuring the reinforcing layer 115 include plastics, such as epoxy-based resins, imide-based resins, phenol-based resins, and cyanate-based resins. The materials may contain fillers. Examples of fillers to be contained include silica, kaolin, talc, alumina, and a combination of these. Fibers can also be used in addition to fillers. Examples of applicable fibers include glass cloths (using glass fiber bundles), carbon fiber bundles, polyester fiber bundles, nylon fiber bundles, and aramid fiber bundles. Alternatively, examples of materials configuring the reinforcing layer 115 include metals such as copper, aluminum, nickel, iron, gold, silver, platinum, tungsten, chromium, titanium, tin, lead, and palladium. One of these metals or a combination of two or more of these metals is also applicable. Of these, silver is preferable from the viewpoint of conductivity, Young's modulus, and cost reduction.

The thickness of the reinforcing layer 115 is desirably 1 μm or more, and more desirably 5 μm or more. If the thickness is less than 1 μm, a sufficient bending resistance may not be obtained. If the reinforcing layer 115 is made of a shielding member, the surface resistance value of the reinforcing layer 115 is desirably 1 ohm/sq. or less, and more desirably 0.1 ohms/sq. or less.

FIG. 16A is a cross-sectional view illustrating the terminal portion 116 of the wiring board 200. On the terminal portion 116, the wiring layer 13 including the signal lines 22 is disposed on the base material 12, and the coverlay 14 and the reinforcing layer 115 are not laminated on the signal lines 22. More specifically, the edges of the signal lines 22 are exposed on the terminal portion 116.

FIG. 16B is a cross-sectional view illustrating the portion where the first reinforcing portion 115a of the wiring board 200 is provided. In this region, the wiring board 200 is formed of the base material 12 as an insulating substrate, the wiring layer 13 having the signal lines 22, the coverlay 14 including the bonding layer 14a and the cover layer 14b as insulation layers, and the first reinforcing portion 115a, which are laminated in this order. The first reinforcing portion 115a has higher rigidity than that of the second reinforcing portion 115b. The rigidity is determined by the Young's modulus, thickness, width, length, and opening ratio of the material used. The first reinforcing portion 115a is disposed in the region ranging from an edge of an insulation layer in the X direction to five times the length of the terminal portion 116 in the X direction. The first reinforcing portion 115a is continuously disposed so as to cover the signal lines 22 and the ground lines 133 in the Y direction intersecting with the X direction.

FIG. 16C is a cross-sectional view illustrating the portion where the second reinforcing portion 115b of the wiring board 200 is provided. In this region, the wiring board 200 is formed of the base material 12 as an insulating substrate, the wiring layer 13 having the signal lines 22, the coverlay 14 including the bonding layer 14a and the cover layer 14b as insulation layers, and the second reinforcing portion 115b, which are laminated in this order. The second reinforcing portion 115b has lower rigidity than that of the first reinforcing portion 115a. The second reinforcing portion 115b is disposed in the region from an edge of an insulation layer to more than five times the length of the terminal portion 116 in the X direction.

The wiring board 200 according to the third exemplary embodiment is provided with the first reinforcing portion 115a having higher rigidity than that of the second reinforcing portion 115b in the region from an edge of an insulation layer to five times the length of the terminal portion 116 in the X direction. More specifically, the reinforcing layer 115 having high rigidity is disposed only in the vicinity of the terminal portion 116. Thus, a deformation, such as a swelling, hardly occurs on the terminal portion 116 in bonding between the terminal portion 116 and the conductor pattern 18. Thus, the present exemplary embodiment can provide a flexible wiring board less likely to incur defective bonding than in the mode disclosed in Japanese Patent Application Laid-Open No. 2018-200779. The first reinforcing portion 115a is continuously provided so as to cover the signal lines 22 and the ground lines 133 in the Y direction. This enables preventing a swelling of the terminal portion 116 caused by the deformation due to the shrinkage of the bonding layer 14a between the signal lines 22 during curing or by the difference in rigidity between the region where the signal lines 22 and the ground lines 133 are disposed and the region where these lines are not.

Desirably, the length of the first reinforcing portion 115a in the X direction is at least 0.5 times the length of the terminal portion 116 in the X direction. This is intended to prevent a swelling of the terminal portion 116 more desirably.

The first reinforcing portion 115a may have openings. The shapes of openings are not particularly limited but include rhombus, eclipse, rectangle, and hexagon. Of these shapes, a plurality of shapes may be selected and arranged. As for the opening ratio indicating the area ratio of the openings in a predetermined surface, the opening ratio of the first reinforcing portion 115a is desirably smaller than the opening ratio of the second reinforcing portion 115b. This opening ratio relation makes it easier to make the rigidity of the first reinforcing portion 115a higher than the rigidity of the second reinforcing portion 115b if the same material is used for the first reinforcing portion 115a and the second reinforcing portion 115b. The first reinforcing portion 115a is desirably formed in a solid pattern without openings. Using the same material for the first reinforcing portion 115a and the second reinforcing portion 115b enables facilitating the manufacturing process.

The thickness of the first reinforcing portion 115a is desirably larger than the thickness of the second reinforcing portion 115b.

This thickness relation makes it easier to make the rigidity of the first reinforcing portion 115a higher than the rigidity of the second reinforcing portion 115b if the same material is used for the first reinforcing portion 115a and the second reinforcing portion 115b.

The first reinforcing portion 115a is desirably disposed via a space to the terminal portion 116.

If the first reinforcing portion 115a is disposed via a space to the terminal portion 116, the insulation layer as the cover layer 14b of the coverlay 14 is exposed. This is because the terminal portion 116 and the first reinforcing portion 115a can be prevented being short-circuited if a conductive material is used for the first reinforcing portion 115a. More specifically, the insulation layer is desirably exposed by 4 mm or less in the X direction. If the insulation layer is exposed by more than 4 mm, the effect of preventing a swelling of the terminal portion 116 may possibly become insufficient.

The opening ratio of the second reinforcing portion 115b is desirably 50% or more. The thickness of the second reinforcing portion 115b is desirably 10 μm or less. These conditions are intended to make the rigidity of the second reinforcing portion 115b relatively lower than the rigidity of the first reinforcing portion 115a.

The second reinforcing portion 115b is desirably connected with the first reinforcing portion 115a. More specifically, the first reinforcing portion 115a and the second reinforcing portion 115b are desirably continuously formed because this formation can simplify the manufacturing process.

Wiring lines used for the signal lines 22 have a bandwidth for enabling transmission of the target digital data signal to be handled. With the increase in the amount of signal transmission, it is preferable to configure a set of differential signal wiring lines formed of a pair of the signal lines 22 out of the plurality of the signal lines 22. When configuring the signal lines 22 as differential signal wiring lines, the distance between adjacent signal lines 22 is desirably larger than the distance between the signal lines 22 and the reinforcing layer 115. By making the distance between adjacent signal lines 22 larger than the distance between the signal lines 22 and the reinforcing layer 115, the electromagnetic field generated by the signal can be more deviated in the direction of the reinforcing layer 115, and the favorable transmission characteristics can be obtained. The plurality of the signal lines 22 may include wiring lines for transmitting single-ended signals such as control signals and response signals. The wiring layer 13 may also include the ground lines 133 in addition to the signal lines 22.

The present disclosure will be described in more detail below with reference to exemplary embodiments and comparative examples, but the present disclosure is not limited to the following exemplary embodiments. The method for evaluating (measuring) the wiring boards according to the present disclosure will be described below.

The method for evaluating the wiring boards according to the exemplary embodiments and comparative examples will be described below.

### (Measuring Warpage of Terminal Portion)

We evaluated a warpage of the terminal portion 116 of the wiring board by using a one-shot shape measuring instrument (VR-3200 from KEYENCE CORPORATION). Firstly, the wiring board 200 was placed on a flat measurement stage, light was applied to the terminal portion 116, and the height of the terminal portion 116 was measured. Based on obtained measurement data, a P-V value from a pseudo surface connecting end points of the terminal portion 116 was then measured by using an analysis application (VR-3000G2 from KEYENCE CORPORATION). The evaluation criteria are as follows:
A (Excellent): A P-V value of less than 50 μm
B (Good): A P-V value of 50 μm or more and 75 μm or less
C (Approved): A P-V value of 75 μm or more and 100 μm or less
D (Disapproved): A P-V value of 100 μm or more

### Seventh Exemplary Embodiment

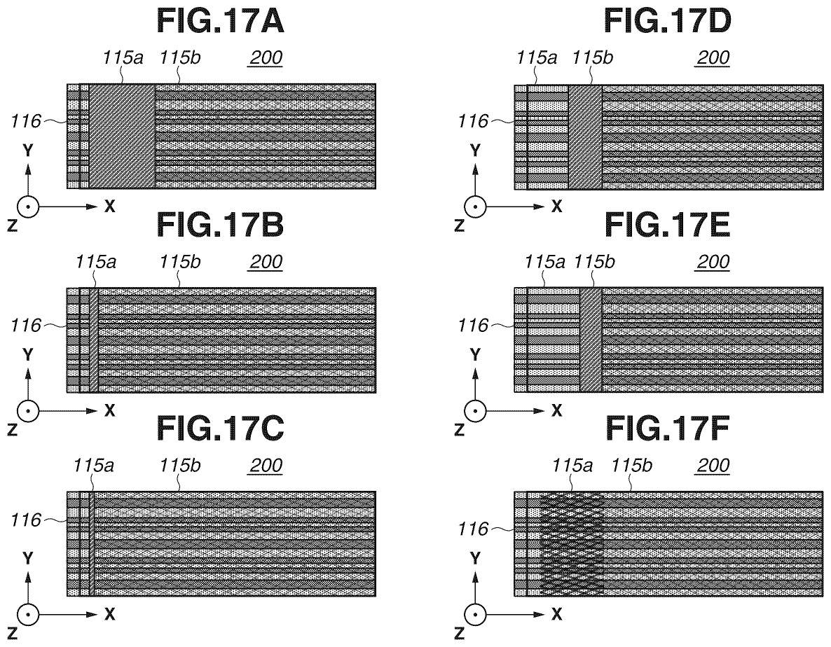

We manufactured the wiring board 200 illustrated in FIG. 17A. As the base material 12 (insulating substrate), a polyimide film with a thickness of 25 μm (Kapton 100H from DU PONT-TORAY CO., LTD.) was prepared. A copper foil with a thickness of 12 μm was laminated on the base material 12 as the wiring layer 13. The signal lines 22 and the ground lines 133 with a total length of 100 mm were formed by using the etching technique. A pair of the signal lines 22 was formed as a pair of differential signal wiring lines, with a 55 μm distance between the signal lines 22 and a 205 μm width of the pair of the signal lines 22. In contrast, the wiring layer 13 was obtained by disposing a ground line 133 with a width of 100 μm on both sides of the pair of the signal lines 22, at a position of 150 μm in the space to an adjacent signal line 22. From the viewpoint of insulation properties of the signal lines 22, the base material 12 was prepared such that the ground lines 133 positioned at both ends of the wiring board 200 are inwardly disposed by 500 μm from the outer side of the wiring board 200.

Next, the coverlay 14 was formed on the wiring layer 13. The bonding layer 14a was formed by using an adhesive with a thickness of 25 μm, and the cover layer 14b was formed by using a coverlay (CEAM0525KA from Arisawa Manufacturing Co., Ltd.) with a thickness of 15 μm, resulting in a total thickness of 37.5 μm. In this case, the signal lines 22 are exposed from the edge of the wiring board 200, and then the terminal portion was provided. Next, the reinforcing layer 115 was formed on the coverlay 14. The reinforcing layer 115 was formed by printing a silver paste (DD-1630L-245 from Kyoto Elex Co., Ltd.) by using a screen printer (MT-320T from Micro-tec Co., Ltd.). In this case, the reinforcing layer 115 was formed by adjusting the opening pattern of the screen-printing plate to print two different patterns for the first reinforcing portion 115a and the second reinforcing portion 115b having different opening shapes. The first reinforcing portion 115a was formed in a solid pattern with a thickness of 20 μm in the range from the 1 mm to 7.5 mm positions from the edge of the terminal portion 116 on the side of the coverlay 14 in the X direction. The first reinforcing portion 115a was formed so as to intersect with all of the signal lines 22 and the ground lines 133. Continuously from the first reinforcing portion 115a, the second reinforcing portion 115b was formed in a rhombus mesh pattern with a thickness of 5 μm and a line width of 58 μm such that the longitudinal direction of the openings is parallel to the signal lines 22. Each opening has a length of 2,000 μm in the X direction and a length of 500 μm in the Y direction. Thus, the wiring board 200 according to the seventh exemplary embodiment was obtained.

### Eighth Exemplary Embodiment

As illustrated in FIG. 17B, the first reinforcing portion 115a of the reinforcing layer 115 was formed in the range from 1 mm to 1.75 mm positions from the edge of the terminal portion 116 on the side of the coverlay 14 in the X direction. Other portions were formed in a similar way to the seventh exemplary embodiment. Thus, the wiring board 200 according to the eighth exemplary embodiment was obtained.

### Ninth Exemplary Embodiment

As illustrated in FIG. 17C, the first reinforcing portion 115a of the reinforcing layer 115 was formed in the range from 1 mm to 1.45 mm positions from the edge of the terminal portion 116 on the side of the coverlay 14 in the X direction. Other portions were formed in a similar way to the seventh exemplary embodiment. Thus, the wiring board 200 according to a ninth exemplary embodiment was obtained.

### Tenth Exemplary Embodiment

As illustrated in FIG. 17D, the first reinforcing portion 115a of the reinforcing layer 115 was formed in the range from 4 mm to 7.5 mm positions from the edge of the terminal portion 116 on the side of the coverlay 14 in the X direction. Other portions were formed in a similar way to the seventh exemplary embodiment. Thus, the wiring board 200 according to a tenth exemplary embodiment was obtained.

### Eleventh Exemplary Embodiment

As illustrated in FIG. 17E, the first reinforcing portion 115a of the reinforcing layer 115 was formed in the range from 5 mm to 7.5 mm positions from the edge of the terminal portion 116 on the side of the coverlay 14 in the X direction. Other portions were formed in a similar way to the seventh exemplary embodiment. Thus, the wiring board 200 according to an eleventh exemplary embodiment was obtained.

### Twelfth Exemplary Embodiment

As illustrated in FIG. 17F, the first reinforcing portion 115a of the reinforcing layer 115 was formed in a rhombus mesh pattern with a thickness of 12 μm and a line width of 125 μm in the range from the 1 mm to 7.5 mm positions from the edge of the terminal portion 116 on the side of the coverlay 14 in the X direction such that the longitudinal direction of the openings is parallel to the signal lines 22. Each opening has a length of 2,000 μm in the X direction and a length of 500 μm in the Y direction. Other portions were formed in a similar way to the seventh exemplary embodiment. Thus, the wiring board 200 according to a twelfth exemplary embodiment was obtained.

### Fourth Comparative Example

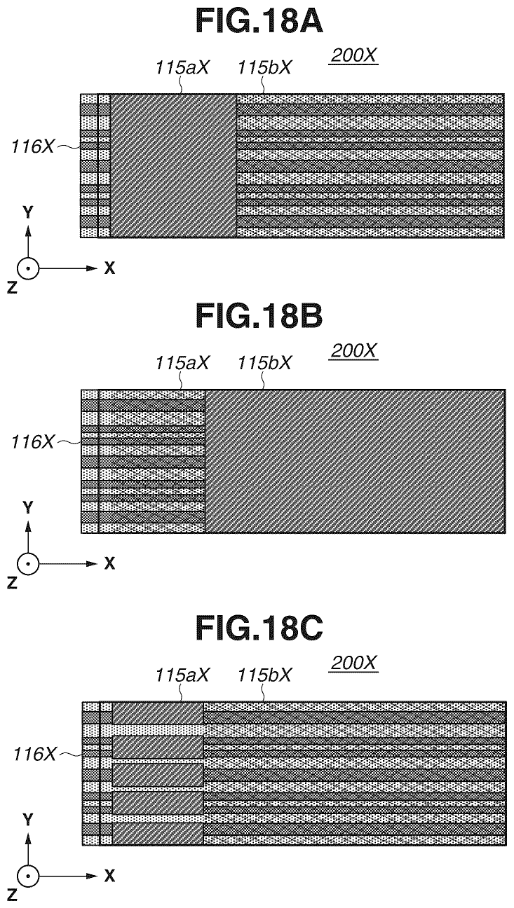

As illustrated in FIG. 18A, a first reinforcing portion 115aX of a reinforcing layer 115X was formed in the range from the 1 mm to 8 mm positions from the edge of a terminal portion 116X on the side of the coverlay 14 in the X direction. Other portions were formed in a similar way to the seventh exemplary embodiment. Thus, a wiring board 200X according to a fourth comparative example was obtained.

### Fifth Comparative Example

As illustrated in FIG. 18B, the first reinforcing portion 115aX of the reinforcing layer 115X was formed in a rhombus mesh pattern with a thickness of 5 μm and a line width of 58 μm in the range from the 1 mm to 7.5 mm positions from the edge of the terminal portion 116X on the side of the coverlay 14 in the X direction such that the longitudinal direction (X direction) of the openings is parallel to the signal lines 22. Each opening has a length of 2,000 μm in the X direction and a length of 500 μm in the Y direction. Adjacently to the first reinforcing portion 115aX, a second reinforcing portion 115bX was formed in a solid pattern with a thickness of 20 μm. Other portions were formed in a similar way to the seventh exemplary embodiment. Thus, the wiring board 200 according to a fifth comparative example was obtained.

### Sixth Comparative Example

As illustrated in FIG. 18C, the first reinforcing portion 115aX of the reinforcing layer 115X was formed in a solid pattern that continuously intersects with none of the signal lines 22 and the ground lines 133. Other portions were formed in a similar way to the seventh exemplary embodiment. Thus, the wiring board 200 according to a sixth comparative example was obtained.

TABLE 2

| | | Seventh | Eighth | Ninth | Tenth | Eleventh |
|---|---|---|---|---|---|---|
| | | exemplary | exemplary | exemplary | exemplary | exemplary |
| | | embodiment | embodiment | embodiment | embodiment | embodiment |
| Terminal portion [mm] | | 1.5 | 1.5 | 1.5 | 1.5 | 1.5 |
| First reinforcing | A: Distance | 1 | 1 | 1 | 4 | 5 |
| portion | from terminal | | | | | |
| | portion [mm] | | | | | |
| | B: Length in | 6.5 | 0.75 | 0.45 | 3.5 | 2.5 |
| | signal line | (4.33 times) | (0.5 times) | (0.3 times) | (2.67 times) | (1.66 times) |
| | direction [mm] | | | | | |
| | (A + B)/Region | 5 times | 1.16 times | 0.97 times | 5 times | 5 times |
| | A | | | | | |
| | Intersection | ∘ | ∘ | ∘ | ∘ | ∘ |
| | with signal | | | | | |
| | lines | | | | | |
| | Opening ratio | 0 | 0 | 0 | 0 | 0 |
| | [%] | | | | | |
| | Thickness | 20 | 20 | 20 | 20 | 20 |
| | [μm] | | | | | |
| | Pattern | Solid | Solid | Solid | Solid | Solid |
| | Material | Silver | Silver | Silver | Silver | Silver |
| Second | Thickness | 5 | 5 | 5 | 5 | 5 |
| reinforcing | [μm] | | | | | |
| portion Region | Opening ratio | 70 | 70 | 70 | 70 | 70 |
| 202 | [%] | | | | | |
| | Pattern | Mesh | Mesh | Mesh | Mesh | Mesh |
| | Material | Silver | Silver | Silver | Silver | Silver |

| | | | | | |
|---|---|---|---|---|---|
| Evaluation: Amount of warpage | 39 | 62 | 84 | 64 | 78 |
| [μm] | A | B | C | B | C |

| | | Twelfth | Fourth | Fifth | Sixth |
|---|---|---|---|---|---|
| | | exemplary | comparative | comparative | comparative |
| | | embodiment | example | example | example |
| Terminal portion [mm] | | 1.5 | 1.5 | 1.5 | 1.5 |
| First reinforcing | A: Distance | 1 | 1 | 1 | 1 |
| portion | from terminal | | | | |
| | portion [mm] | | | | |
| | B: Length in | 6.5 | 8 | 6.5 | 6.5 |
| | signal line | (4.33 times) | (5.33 times) | (4.33 times) | (4.33 times) |
| | direction [mm] | | | | |
| | (A + B)/Region | 5 times | 6 times | 5 times | 5 times |
| | A | | | | |
| | Intersection | ∘ | ∘ | ∘ | x |
| | with signal | | | | |
| | lines | | | | |
| | Opening ratio | 35 | 0 | 70 | 0 |
| | [%] | | | | |
| | Thickness | 12 | 20 | 5 | 20 |
| | [μm] | | | | |
| | Pattern | Mesh | Solid | Mesh | Solid |
| | Material | Silver | Silver | Silver | Silver |
| Second | Thickness | 5 | 5 | 20 | 5 |
| reinforcing | [μm] | | | | |
| portion Region | Opening ratio | 70 | 70 | 0 | 70 |
| 202 | [%] | | | | |
| | Pattern | Mesh | Mesh | Solid | Mesh |
| | Material | Silver | Silver | Silver | Silver |

| | | | | |
|---|---|---|---|---|
| Evaluation: Amount of warpage | 86 | 112 | 145 | 160 |
| [μm] | C | D | D | D |

As illustrated in Table 2, the wiring boards 200 according to the seventh to the twelfth exemplary embodiments can prevent a swelling of the terminal portion 116. When the seventh and the eighth exemplary embodiments are compared, the amount of warpage according to the seventh exemplary embodiment is smaller than that according to the eighth exemplary embodiment. The seventh exemplary embodiment provides a larger area occupied by the first reinforcing portion 115a in the range from the edge of the terminal portion 116 on the side of the coverlay 14 to five times the length of the terminal portion 116 in the X direction and provides higher rigidity than the eighth exemplary embodiment. Thus, the seventh exemplary embodiment can block to a further extent of a swelling caused by the shrinkage of the bonding layer of the wiring portion than the eighth exemplary embodiment. When the seventh and the tenth exemplary embodiments are compared, the amount of warpage according to the seventh exemplary embodiment is smaller than that according to the tenth exemplary embodiment. The seventh exemplary embodiment is provided with the first reinforcing portion 115a at a region closer to the terminal portion 116 and hence the terminal portion 116 can be more reinforced than the tenth exemplary embodiment. In addition, the seventh exemplary embodiment enables preventing the shrinkage of the bonding layer occurring in the region where the reinforcing layer 115 is not provided. According to the fourth comparative example, the distance from the edge of the terminal portion 116X on the side of the coverlay 14 to the edge of the first reinforcing portion 115a is longer than five times the length of the terminal portion 116X. With this configuration, the shrinkage of the reinforcing layer 115 itself causes a swelling of the terminal portion 116X. According to the fifth comparative example, the first reinforcing portion 115aX has lower rigidity than that of the second reinforcing portion 115bX. This configuration is unable to provide sufficient rigidity for preventing a swelling transmitted from the wiring portion in the vicinity of the terminal portion 116X. Since the rigid region is provided in a large area like the fourth comparative example, the shrinkage of the reinforcing layer 115X itself increases. According to the sixth comparative example, the first reinforcing portion 115a continuously intersects with none of the signal lines 22 and the ground lines 133. With this configuration, the shrinkage of the adhesive between the signal lines 22 or the difference in rigidity between the region where the signal lines 22 are disposed and the region where the signal lines 22 are not disposed causes a swelling in accordance with the arrangements of the signal lines 22. In addition, the influence of the shrinkage increases with decreasing binding force of the adhesive between the signal lines 22.

The above-described exemplary embodiments can be suitably modified without departing from the technical concept of the present disclosure.

For example, a plurality of exemplary embodiments can be combined. One end of the flexible wiring board may be configured according to the first exemplary embodiment, and the other end thereof may be configured according to the third exemplary embodiment. The flexible wiring board according to the third exemplary embodiment can be used for the second exemplary embodiment. Contents according to at least one exemplary embodiment can be partly deleted or replaced.

New contents can also be added to at least one exemplary embodiment. The disclosure of the present specification includes not only the explicit descriptions of the present specification but also all of the contents prehensible from the present specification and the drawings attached thereto.

The disclosure of the present specification includes a complementary set of the individual concepts described in the present specification. More specifically, if the present specification includes a description “A is larger than B”, for example, the present specification discloses a description “A is not larger than B” even if a description “A is not larger than B” is omitted. This is because the description “A is larger than B” premises the consideration of a case where “A is not larger than B”.

The present disclosure makes it possible to provide a flexible wiring board having a function superior to the prior art.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of priority from Japanese Patent Applications No. 2023-121791, filed Jul. 26, 2023, and No. 2024-070113, filed Apr. 23, 2024, which are hereby incorporated by reference herein in their entirety.

What is claimed is:

1. A flexible wiring board comprising:
a plurality of signal lines;
a shielding layer disposed to overlap with the plurality of signal lines in a planar view; and
an insulating member disposed on a side opposite to a side where the shielding layer for the plurality of signal lines is disposed,
wherein the shielding layer is provided with openings,
wherein the shielding layer includes a first region having an opening ratio higher than a predetermined value, and a second region having an opening ratio lower than the opening ratio of the first region, and
wherein the second region is disposed at a position where the second region overlaps with the insulating member and the plurality of signal lines in a planar view, and
wherein a boundary between the first region and the second region is disposed via a space to the insulating member in a planar view.

2. The flexible wiring board according to claim 1, wherein the insulating member is a reinforcing plate having a larger thickness than a thickness of the shielding layer.

3. The flexible wiring board according to claim 1, wherein the shielding layer in the first region is formed in a mesh pattern.

4. The flexible wiring board according to claim 1, wherein the shielding layer in the second region is formed in a mesh pattern.

5. The flexible wiring board according to claim 4, wherein the shielding layer in the first region has a smaller line width than a line width of the shielding layer in the second region.

6. The flexible wiring board according to claim 5, wherein the line width of the shielding layer in the second region is equal to or greater than 1.5 times the line width of the shielding layer in the first region.

7. The flexible wiring board according to claim 1, wherein the shielding layer in the second region is provided with no openings.

8. The flexible wiring board according to claim 1, wherein the first region has an opening ratio of 60% or more.

9. The flexible wiring board according to claim 1, wherein the second region has an opening ratio of 50% or less.

10. The flexible wiring board according to claim 1, wherein the boundary between the first region and the second region is disposed more on the side of the insulating member than the edge surface on the side opposite to the second region, the edge surface being among edge surfaces of the first region and intersecting with the plurality of signal lines.

11. The flexible wiring board according to claim 10, wherein the boundary between the first region and the second region is disposed at a position of 10% or less of the distance from the insulating member to the edge surface.

12. The flexible wiring board according to claim 1, wherein the shielding layer further includes a third region having an opening ratio lower than the opening ratio of the first region, and the first region is disposed between the second region and the third region.

13. The flexible wiring board according to claim 12, wherein the boundary between the first region and the second region is disposed more on the side of the insulating member than a boundary between the first region and the third region.

14. The flexible wiring board according to claim 1, wherein a hardness of the insulating member is higher than a hardness of the shielding layer.

15. The flexible wiring board according to claim 1, wherein an insulating material is disposed between the insulating member and the plurality of signal lines.

16. The flexible wiring board according to claim 15, wherein the insulating member has a thickness larger than a thickness of the insulating material.

17. The flexible wiring board according to claim 1,
wherein the plurality of signal lines are differential signal wiring lines comprising a first signal line and a second signal line adjacent to the first signal line, and
wherein a distance between the first signal line and the second signal line is larger than a distance between the first signal line and the shielding layer.

18. An electronic module comprising:
the flexible wiring board according to claim 1;
a rigid wiring board connected with an edge of the flexible wiring board; and
an electronic component mounted on the rigid wiring board.

19. The electronic module according to claim 18, wherein the electronic component includes an image sensor.

20. An electronic unit comprising:
the electronic module according to claim 18; and
a driving apparatus configured to move the rigid wiring board.

21. An electronic apparatus comprising:
the electronic module according to claim 18; and
a circuit board connected with an edge different from the edge of the flexible wiring board,
wherein the circuit board is mounted with a processor for processing a signal output from the electronic component.

22. An electronic apparatus comprising:
the electronic module according to claim 18; and
a housing storing the electronic module,
wherein the flexible wiring board is stored in the housing in a bent state, and
wherein the shielding layer is disposed on an outer surface of bending surfaces of the flexible wiring board.
